(19) United States
(12) Patent Application Publication
(10) Pub. No.: US 2002/0118029 A1
(43) Pub. Date: Aug. 29, 2002

(54) Probe card and contactor

(76) Inventor: Rikihito Yamasaka, Kitakoma-gun (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(21) Appl. No.: 10/078,695

(22) Filed: Feb. 21, 2002

Related U.S. Application Data
(63) Continuation-in-part of application No. 09/567,026, filed on May 8, 2000, now abandoned.

(30) Foreign Application Priority Data
May 14, 1999 (JP) 11-134794

(51) Int. Cl. G01R 31/02

(52) U.S. Cl. 324/754

(57) ABSTRACT

A probe card comprises a connecting board and a conversion board. The connecting board has first terminals on a first surface and second terminals on a second surface. The first terminals are electrically connected to the second terminals via electric wiring. The conversion board, smaller than the connecting board, has third terminals on a third surface and fourth terminals on a fourth surface. The third terminals are electrically connected to the fourth terminals via electric wiring. The fourth terminals on the fourth surface are arranged in an area narrower than that in which the third terminals are arranged on the third surface. The second terminals have resilient terminals, which are resiliently brought into contact with the third terminals.

### CROSS-REFERENCE TO RELATED APPLICATIONS

This is a Continuation-in-Part application of U.S. patent application Ser. No. 09/567,026, filed May 8, 2000, now abandoned, the entire contents of which are incorporated herein by reference.

This application is based upon and claims the benefit of priority from the prior Japanese Patent Application No. 11-134794, filed May 14, 1999, the entire contents of which are incorporated herein by reference.

### BACKGROUND OF THE INVENTION

1. Field of the Invention

The present invention relates to a probe card and a contactor to be loaded in a probe apparatus.

2. Description of the Related Art

A conventional probe card comprises, for example, a main board constituted by a print wiring board, a support frame an end of which is attached to a hole formed in a central portion of the main board, and a probe (e.g., a tungsten probe) supported by the support frame. The probe card has a probe needle, which is brought into contact with a test electrode of an object to be tested (e.g., a semiconductor wafer), so that the object is connected to a tester.

At present, the performance of the semiconductor manufacturing apparatus has been improved rapidly. An object to be tested is highly integrated, and the number of test electrodes of the object has been considerably increased. Moreover, the pitch of the test electrodes becomes smaller and smaller. In accordance with the high-integration, the probe card is required to have an increased number of probes. However, the conventional probe card of the aforementioned structure, in which an end of the probe is connected to the main board, cannot fully satisfy the requirements for increasing the number of probes and reducing the pitch of the probes. Therefore, a contactor having probe needles provided on, for example, a ceramic substrate, has been developed. The contactor has been more adapted to increase in number of probe needles and reduction in pitch of the needles.

The contactor is connected to the main board by connecting means, such as POGO pins. As an IC chip has been very highly integrated in recent years, the mounting technology has been remarkably developed and moved into the age of chip scale packaging (CSP) is going to start. In a chip scale package, for example, solder bumps are used to connect IC chips, and the IC chips are tested through the solder bumps.

If POGO pins are used as connecting means as in the conventional probe card, the requirements for increase in number of probe needles and reduction in pitch of the needles of the contactor can be satisfied to a certain degree by decreasing the size of the POGO pins. However, since the POGO pins are to be inserted to holes in the board, the more the number of probe needles, the more labor required for the connection of the POGO pins. In addition, the layout for the POGO pins does not have a sufficient degree of freedom due to a limitation of wiring. For example, because of inconvenience in wiring, it is substantially difficult to arrange POGO pins in a limited portion of the contactor in order to create a space for the increased number of probe needles. Moreover, to add resilience to a POGO pin, the POGO pin must have at least a length required for a coil spring. Since the electric resistance of the coil spring cannot be reduced beyond a certain value, the POGO pin has a problem that it cannot be fully adapted to high speed signal processing.

Further, when an object to be tested having solder bumps is tested with a probe, as shown in FIG. 5, a flat surface at the top end of a probe needle 1 is brought into contact with a solder bump L. In this case, solder scraps L′ easily adhere to the flat surface at the top end of the probe needle 1. The adhered solder scraps L′ cause a problem of defective connection between the top end of the probe needle 1 and the solder bump.

### BRIEF SUMMARY OF THE INVENTION

The present invention has been made to solve at least one of the problems of the conventional art as described above.

An object of the present invention to increase the degree of freedom of layout of wiring terminals of a board for interconnection, such as a main board, in accordance with the increase in number of probes and decrease in pitch of the probes of a contactor.

Another object of the present invention is to provide a probe card which can reliably test electric characteristics of an object having a high processing speed.

Still another object of the present invention is to provide a contactor which can prevent defective connection between the probe needle and an electrode to be tested.

According to a first aspect of the present invention, there is provided a probe card comprising:

a connecting board having first and second surfaces, the first surface having first terminals, the second surface having second terminals, and the first terminals being electrically connected to the second terminals, respectively, via electric wiring; and

a conversion board, which is smaller than the connecting board, the conversion board having third and fourth surfaces, the third surface having third terminals, the fourth surface having fourth terminals, the third terminals being electrically connected to the fourth terminals, respectively, via electric wiring, the fourth terminals on the fourth surface being arranged in an area narrower than that in which the third terminals are arranged on the third surface, and the conversion board facing the connecting board such that the third surface faces the second surface of the connecting board and the third terminals are electrically connected to the second terminals,

the second terminals having resilient terminals, which are resiliently brought into contact with the third terminals.

In the probe card, it is preferable that the resilient terminals be fixed to the second surface of the connecting board.

Preferably, the resilient terminals are deformable in themselves.

The resilient terminals may be V-shaped.

In the probe card, it is preferable that the connecting board further comprise a guide member having an opening, through which the resilient terminals are inserted.

Preferably, the probe card further comprises a contactor having probe terminals to be brought into contact with electrodes of an object to be tested, and the probe terminals are electrically connected to the fourth terminals respectively.

In the probe card, it is preferable that each of the probe terminals comprise a blade portion in its top end portion.

It is further preferable that the blade portion include an edge having a relief angle.

Preferably, the blade portion further comprises a capacitor connected to wiring electrically connecting the first, second, third and fourth terminals and the probe terminals.

It is preferable that the capacitor be located on the fourth surface of the conversion board.

The capacitor may be located on the first surface of the connecting board.

According to a second aspect of the present invention, there is provided a probe card comprising:

a connecting board having first and second surfaces, the first surface having first terminals, the second surface having second terminals, and the first terminals being electrically connected to the second terminals, respectively, via electric wiring;

a conversion board, which is smaller than the connecting board, the conversion board having third and fourth surfaces, the third surface having third terminals, the fourth surface having fourth terminals, the third terminals being electrically connected to the fourth terminals, respectively, via electric wiring, the fourth terminals on the fourth surface being arranged in an area narrower than that in which the third terminals are arranged on the third surface, and the conversion board facing the connecting board such that the third surface faces the second surface of the connecting board and the third terminals are electrically connected to the second terminals; and

a capacitor connected to wiring electrically connecting the first, second, third and fourth terminals and probe terminals.

Preferably, the probe card further comprises a contactor, which includes the probe terminals that are to be brought into contact with an electrode of an object to be tested and electrically connected to the fourth terminals respectively.

In the probe card, it is preferable that the capacitor be located on the fourth surface of the conversion board.

The capacitor may be located on the first surface of the connecting board.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a schematic cross-sectional view showing a probe card according to an embodiment of the present invention;

FIGS. 2A and 2B are cross-sectional views showing the relationships between a main board and a conversion board shown in FIG. 1, wherein

FIG. 2A shows a state in which the main board and the conversion board are connected via a plate spring terminal,

and FIG. 2B shows the relationship between the main board and the conversion board when an object is tested;

FIG. 3 is a plane view showing a main part of the main board shown in FIG. 1;

FIGS. 4A and 4B are diagrams for explaining state in which an object having a solder bump is probe-tested by the probe card shown in FIG. 1,

wherein FIG. 4A is a front view and

FIG. 4B is a side view; and

FIG. 5 is a diagram for explaining a state in which an object having a solder bump is probe-tested by the conventional probe card.

### DETAILED DESCRIPTION OF THE INVENTION

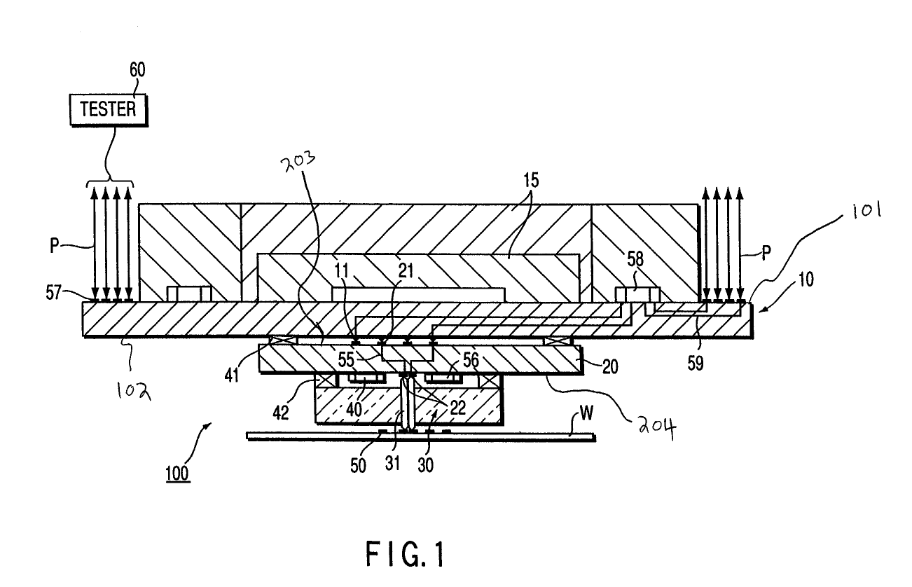

The present invention will be described based on an embodiment shown in FIGS. 1 to 4B.

FIG. 1 shows a probe card of this embodiment. A probe card 100 shown in FIG. 1 comprises a board for interconnection (hereinafter referred to as a main board) 10, a board for conversion (hereinafter referred to as a conversion board) 20 and a contactor 30. A plurality of first terminals (hereinafter referred to as output terminals) 57 are formed on a first surface 101 of the main board 10. A plurality of second terminals (hereinafter referred to as contact terminals) 11 are formed on a second surface 102 thereof.

The output terminals 57 are brought into contact with POGO pins P electrically connected to the side of a tester 60. The output terminals 57 may be arranged in a plurality of ring-like rows. A group of contact terminals 11, for example, arranged in a matrix, may be provided on the lower surface of the main board 10.

The conversion board 20 is smaller than the main board. A plurality of third terminals (hereinafter referred to as first connecting terminals) 21, which are brought into contact with the contact terminals 11 of the main board 10, are formed on the upper surface (a third surface) 203 of the conversion board 20. A plurality of fourth terminals (hereinafter referred to as second connecting terminals) 22, for example, arranged in a matrix, may be provided on the lower surface (a fourth surface) 204 of the conversion board 20. The second connecting terminals 22 on the lower surface 204 of the conversion board 20 are arranged in an area narrower than that of the first connecting terminals 21 on the upper surface 203 of the conversion board 20. Thus, the arrangement of the second connecting terminals 22 is magnified into the arrangement of the first connecting terminals 21. The contactor 30 has probe needles 31. The upper ends of the probe needles 31 are brought into contact with the second connecting terminals 22. The lower ends of the probe needles 31 are brought into contact with measuring electrodes of an object to be tested (hereinafter referred to as a semiconductor wafer) W.

The probe card electrically connects the measuring electrodes of the semiconductor wafer W and the tester 60 through the probe needles 31, the second connecting terminals 22, a first wiring 55, the first connecting terminals 21, a second wiring 59, the output terminals 57 and the POGO pins P. Under this interconnection, the electric characteristics of the semiconductor wafer W can be tested by the tester 60.

The first wiring 55 of the conversion board 20 may includes means (hereinafter referred to as a first capacitor) 40 for removing noise from a test signal. The first capacitor 40 is preferably connected in the shortest distance from the probe needle 31. The second wiring of the main board 10 may also have a second capacitor for removing noise. The first and second capacitors can be provided in order to stabilize a signal and a power source.

In FIG. 1, reference numerals 41 and 42 denote spacers. The spacers may be provided on either the conversion board 20 or the contactor 30. The first capacitor may be arranged in proximity to the second connecting terminals 22 in a space defined by the spacers 42.

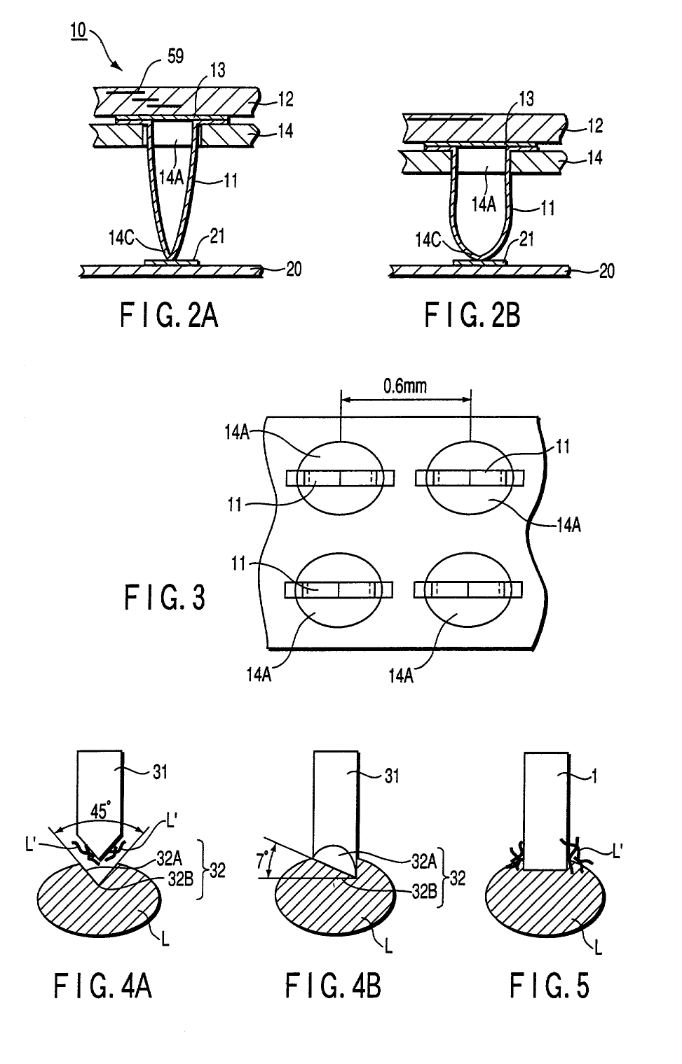

As shown in FIGS. 2A and 2B, the main board 10 of this embodiment comprises a print wiring board 12 of a multi-layered wiring structure, a plurality of wiring terminals 13 arranged on the lower surface of the print wiring board 12, a guide sheet 14 having guide holes 14A, and the contact terminals 11 respectively fitted to the guide holes 14A of the guide sheet 14. The guide holes 14A of the guide sheet 14 are formed in accordance with the positions of the wiring terminals 13. As shown in the drawings, the contact terminal 11 may be formed as a plate spring terminal including a substantially V-shaped top end and a proximal end having a horizontal flange portion. The plate spring terminal is supported by its flange portion at the periphery of the guide hole 14A, so that it may not be removed from the guide hole 14A. In the following, the contact terminal 11 is described as the plate spring terminal 11. The plate spring terminal 11 fitted in the guide hole 14A is brought into contact with the wiring terminal 13 and electrically connected thereto. Referring back to FIG. 1, a reinforcing member 15 may be fixed to the upper surface of the main board 10 to prevent the main board 10 from heat deformation. The output terminals 57 to be in contact with the POGO pins P are arranged, for example, like a ring.

The plate spring terminal (resilient terminal) 11 may be formed of any resilient conductive metal. The metal is preferably, for example, beryllium-copper alloy or gold. The thickness of the plate spring terminal 11 is preferably 10-30 μm, and the width thereof is preferably 40-60 μm, and the height thereof is preferably 1-3 mm from the surface of the wiring terminal 13. The guide sheet 14 may be made of any insulating material, preferably plastic film such as polyimide film. The diameter of the guide hole 14A varies depending on the size of the first connecting terminal 21 of the conversion board 20. For example, it may be set to about 0.1-0.4 mm.

The plate spring terminal 11 can be easily fitted to the print wiring board 12 without failure and electrically connected to the wiring terminal 13 only by inserting the plate spring terminal 11 in the guide hole 14A of the guide sheet 14. With this fitting structure of the plate spring terminal 11, the plate spring terminals 11 can be correspondingly connected to the first connecting terminals 21 arranged in a matrix in the conversion board 20. Further, since the electric resistance of the plate spring terminal 11 itself can be suppressed to a minimum, the object, such as an IC chip, can be tested at a high speed.

Moreover, since the plate spring terminal 11 has a very simple structure, the production cost can be reduced. In the case where a POGO pin is used in place of the plate spring terminal 11, the cost for manufacturing the POGO pin is inevitably high, since the POGO pin has a complicated structure and the spring coil thereof has a high electric resistance as described before. Therefore, a great deal of labor is required to connect POGO pins to the print wiring board, resulting in increase in production cost of the probe card 100.

FIG. 3 is an enlarged plan view showing a part of the main board 10. The plate spring terminals 11 are arranged at pitch of 0.6 mm. The diameter of the guide hole 14A may be set to 0.3-0.4 mm. The first connecting terminals 21 are arranged on the upper surface of the conversion board 20 at the same pitch as the plate spring terminals 11. The second connecting terminals 22 are arranged in a central portion of the lower surface of the conversion board 20 in a matrix at pitch reduced from that of the matrix of the first connecting terminals 21 (see FIG. 1). For example, the second connecting terminals 22 is arranged at pitch of 80 μm, the same pitch as that of the probe needles 31 of the contactor 30. Thus, the conversion board 20 has a function for reduction-converting the arrangement of the plate spring terminals 11 of the main board 10 to the arrangement of the probe needles 31 of the contactor 30.

A function of the main board 10 will now be described with reference to FIGS. 2A and 2B. When the probe card 100 is assembled, the conversion board 20 is connected by fastening members (e.g., set screws) to the lower surface of the main board 20 via the spacers 41. In this state, as shown in FIG. 2A, the top end of the plate spring terminal 11 is brought into contact with the first connecting terminal 21 of the conversion board 20. Then, when the conversion board 20 is gradually fastened by the fastening members, the conversion board 20 gradually approaches to the main board 10 against the spring force of the plate spring terminal 11. Finally, the plate spring terminal 11 is brought into contact with the rear surface of the main board 10, in the state where it expands right and left, as shown in FIG. 2B. The spacers 41 are provided to maintain the space to allow the plate spring terminal 11 to project from the main board 10 (precisely, the guide sheet 14).

FIGS. 4A and 4B are enlarged schematic views showing the top end portion of the probe needle 31 of the contactor 30. In the drawings, the top end of the probe needle 31 is in contact with a solder bump L of an IC chip. As shown in FIGS. 4A and 4B, the top end of the probe needle 31 has a blade portion 32. The blade portion 32 includes an edge having a relief angle. The blade portion 32 enters the solder bump L and electrically connects the probe needle 31 and the IC chip.

As shown in FIGS. 4A and 4B, the blade portion 32 is formed at the top end of the probe needle 31 having, for example, a cylindrical shape. The blade portion 32 has symmetrical blade surfaces 32A. For example, the two blade surfaces 32A may cross at an angle of 45°. An edge 32B is formed at the intersection of the blade surfaces. It is preferable that the edge 32B be inclined at an angle of about 7° with respect to the horizontal. The inclination angle is a relief angle. Therefore, when the probe needle 31 contacts to the solder bump L, the lower end of the edge 32B of the blade portion 32 first enters the solder bump L and the left and right blade surfaces 32A are brought into contact with the solder bump L, thereby securing electrical contact between the probe needle 31 and the solder bump L. When the blade portion 32 enters the solder bump L, solder scraps may be generated. However, as shown in FIG. 4A with exaggeration, the solder scraps are moved upward and kept away from the blade surfaces 32A, and do not adhere thereto.

As has been described above, according to the probe card of the embodiment of the present invention, the first capacitor is provided in the conversion board 20 in proximity to the second connecting terminals. With this structure, noise in a signal transmitted between the tester 60 and the wafer W can be efficiently reduced. In the main board 10 of the embodiment, since the substantially V-shaped plate spring terminals 11 are connected to the wiring terminals 13, it is unnecessary to form holes in the print wiring board 12. As a result, the degree of freedom in design for arranging wires on the print wiring board 12 is increased. Consequently, it is possible to produce a probe card at a low cost, which can be adapted to the increase in number and the reduction in pitch of arrangement of the probe needles 31, and in which the wiring terminals 13 and the plate spring terminals 11 can be connected very easily to the lower surface of the print wiring board 12. The conversion board 20 interposed between the main board 10 and the contactor 30 reduction-converts the arrangement of the wiring terminals 13 of the main board 10 to the arrangement of the contactor 30. Since the plate spring terminals 11, having a low resistance, are used as means for connecting the main board 10 and the conversion board 20, the frequency characteristic of the probe card 10 can be improved so as to be adapted to the high-speed processing of an object to be tested.

Further, the embodiment employs the structure in which the plate spring terminals 11 are detachably connected to the print wiring board 12 and the structure in which the plate spring terminals 11 are concentrated in a central portion of the print wiring board 12. Therefore, the plate spring terminals 11 of the main board 10 can be arranged in accordance with the arrangement of the probe needles of the contactor 30. As a result, a plurality of kinds of contactor 30, having an increased number of probe needles arranged at small pitch, can be combined in the same main board 10.

Furthermore, since the probe needle 31 of this embodiment has at its top end the blade portion 32 which is inserted in the solder bump L, the solder scraps L′ generated in the test do not adhere to the blade surfaces 32A of the probe needle 31. Therefore, a reliable test can be continuously carried out. In addition, since the edge 32B of the blade portion 32 has a relief angle, it can be smoothly inserted in the solder bump L.

In the above embodiment, the plate spring terminals are sandwiched between the guide sheet and the print wiring board. Alternatively, the substantially V-shaped plate spring terminal may be inserted into a guide sheet or a guide insulating layer, or fixed thereto by welding or soldering. Although the probe card of the above embodiment has the probe needles 31 for carrying out a test through soldering bumps, the probe card and the contactor of the present invention can test an object having no solder bumps by using various types of terminal (e.g., bump terminals) as probe needles.

According to the invention recited in claims 1 and 15, it is possible to provide a probe card in which the degree of freedom of layout of wiring terminals on the main board can be increased in accordance with the increase in number of probe needles and decrease in pitch of the needles of a contactor, and which can reliably test electric characteristics of an object having a high processing speed.

Furthermore, according to the invention of claims 12 to 15, it is possible to provide a probe card and a contactor which can carry out a test without causing contact defect due to solder bump scraps.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A probe card comprising:
a connecting board having first and second surfaces, the first surface having first terminals, the second surface having second terminals, and the first terminals being electrically connected to the second terminals, respectively, via electric wiring; and
a conversion board, which is smaller than the connecting board, the conversion board having third and fourth surfaces, the third surface having third terminals, the fourth surface having fourth terminals, the third terminals being electrically connected to the fourth terminals, respectively, via electric wiring, the fourth terminals on the fourth surface being arranged in an area narrower than that in which the third terminals are arranged on the third surface, and the conversion board facing the connecting board such that the third surface faces the second surface of the connecting board and the third terminals are electrically connected to the second terminals,
the second terminals having resilient terminals, which are resiliently brought into contact with the third terminals.

2. A probe card according to claim 1, wherein the resilient terminals are fixed to the second surface of the connecting board.

3. A probe card according to claim 1, wherein the resilient terminals are deformable in themselves.

4. A probe card according to claim 1, wherein the resilient terminals are V-shaped.

5. A probe card according to claim 1, wherein the connecting board further comprises a guide member having an opening, through which the resilient terminals are inserted.

6. A probe card according to claim 1, further comprising a contactor having probe terminals to be brought into contact with electrodes of an object to be tested, the probe terminals being electrically connected to the fourth terminals respectively.

7. A probe card according to claim 6, wherein each of the probe terminals comprises a blade portion in its top end portion.

8. A probe card according to claim 7, wherein the blade portion includes an edge having a relief angle.

9. A probe card according to claim 6, further comprising a capacitor connected to wiring electrically connecting the first, second, third and fourth terminals and the probe terminals.

10. A probe card according to claim 9, wherein the capacitor is located on the fourth surface of the conversion board.

11. A probe card according to claim 9, wherein the capacitor is located on the first surface of the connecting board.

12. A probe card comprising:
a connecting board having first and second surfaces, the first surface having first terminals, the second surface having second terminals, and the first terminals being electrically connected to the second terminals, respectively, via electric wiring;
a conversion board, which is smaller than the connecting board, the conversion board having third and fourth surfaces, the third surface having third terminals, the fourth surface having fourth terminals, the third terminals being electrically connected to the fourth terminals, respectively, via electric wiring, the fourth terminals on the fourth surface being arranged in an area narrower than that in which the third terminals are arranged on the third surface, and the conversion board facing the connecting board such that the third surface faces the second surface of the connecting board and the third terminals are electrically connected to the second terminals; and
a capacitor connected to wiring electrically connecting the first, second, third and fourth terminals and probe terminals.

13. A probe card according to claim 12, further comprising a contactor, which includes the probe terminals that are to be brought into contact with an electrode of an object to be tested and electrically connected to the fourth terminals respectively.

14. A probe card according to claim 12, wherein the capacitor is located on the fourth surface of the conversion board.

15. A probe card according to claim 12, wherein the capacitor is located on the first surface of the connecting board.
